(19) United States
(12) Patent Application Publication
(10) Pub. No.: US 2006/0131598 A1
(43) Pub. Date: Jun. 22, 2006

(54) CMOS image sensor and method for fabricating the same

(76) Inventor: Kwan Ju Koh, Bucheon-city (KR)

Correspondence Address: MCKENNA LONG & ALDRIDGE LLP, 1900 K STREET, NW, WASHINGTON, DC, 20006, US

(21) Appl. No.: 11/312,600

(22) Filed: Dec. 21, 2005

(30) Foreign Application Priority Data
Dec. 21, 2004 (KR) 2004-0109602

(51) Int. Cl. H01L 33/00

(52) U.S. Cl. 257/98

(57) ABSTRACT

A CMOS image sensor and a method for fabricating the same with improved light-receiving efficiency of the active device, e.g., a photodiode. The CMOS image sensor includes at least one photodiode positioned on a semiconductor substrate; and a microlens disposed above each photodiode, wherein the microlens is formed of a polymer exhibiting excellent transmissivity.

### CROSS-REFERENCE TO RELATED APPLICATIONS

This application claims the benefit of Korean Application No. 10-2004-0109602 filed on Dec. 21, 2004, which is hereby incorporated by reference for all purposes as if fully set forth herein.

### BACKGROUND OF THE INVENTION

1. Field of the Invention

The present invention relates to image sensors, and more particularly, to a CMOS image sensor having improved light-receiving efficiency and a method for fabricating the same.

2. Discussion of the Related Art

Image sensors are semiconductor devices for converting an optical image into an electrical signal and include charge-coupled devices and complementary metal-oxide-semiconductor (CMOS) image sensors.

A general charge-coupled device includes an array of photodiodes converting light signals into electrical signals, a plurality of vertical charge-coupled devices formed between each vertical photodiode aligned in a matrix-type configuration and vertically transmitting electrical charges generated from each photodiode, a horizontal charge-coupled device for horizontally transmitting the electrical charges transmitted by each of the vertical charge-coupled devices, and a sense amplifier for sensing and outputting the horizontally transmitted electrical charges. Charge-coupled devices, have the disadvantages of complicated driving method, high power consumption, and complicated fabrication processes requiring multi-phased photo-processes. Additionally, integration of complementary circuitry such as a control circuit, a signal processor, and an analog-to-digital converter into a single-chip charge coupled device is difficult, thereby hindering development of compact-sized products using such image sensors.

CMOS image sensors, on the other hand, adopt CMOS technology using a control circuit and a signal processing circuit as a peripheral circuit and adopt switching technology which allows outputs to be detected using a MOS transistor with each pixel arrayed, thereby detecting an image. Accordingly, a CMOS image sensor uses CMOS fabrication technology, i.e., a simple fabrication method using fewer photolithography steps, enabling an advantageous device exhibiting low power consumption.

Typically, in the aforementioned CMOS image sensor, the photodiode is the active device for generating an optical image based on incident light signals. In such a CMOS image sensor, wherein each photodiode senses incident light and the corresponding CMOS logic circuit converts the sensed light into an electrical signal. Yhe photodiode's photosensitivity increases as more light is able to reach the photodiode. One way of enhancing a CMOS image sensor's photosensitivity is to improve its “fill factor,” i.e., the degree of surface area covered by the photodiodes versus the entire surface area of the image sensor. The fill factor is improved by increasing the size of the area responsive to incident light. Additionally, concentration of incident light onto the photodiode is further facilitated when the quantum efficiency at all wavelengths (white light) is “1.”

A device exhibiting excellent light transmittance, such as a convex microlens for refracting incident light, may be provided to redirect any light that may be incident to the image sensor outside the immediate area of the photodiodes and to concentrate (focus) the incident light on one or more of the photodiodes themselves. In a color image sensor, such a microlens having a predetermined curvature (i.e., a convex lens) may be provided over a color filter layer for passing the light of each color (wavelength). FIG. 1 shows a CMOS image sensor according to the related art wherein three photodiodes 11 are provided for generating electrical signals according to the amount of incident light.

Referring to FIG. 1, a CMOS image sensor according to the related art includes an insulating interlayer 12 formed over the photodiodes 11 located on a substrate surface (not shown), a passivation layer 13 formed on the insulating interlayer, a color (RGB) filter layer 14 formed on the passivation layer, a planarization layer 15 formed on the color filter layer, and a microlens 16 for each photodiode, to thereby focus the incident light through the color filter layer and onto the underlying photodiode. The microlenses 16 are generally formed of a photoresist layer coated on the planarization layer 15 and then patterned using a photolithography process. The patterned photoresist undergoes a reflowing (thermal) process to give each microlens 16 a domed upper surface. Use of photoresist material for microlenses 16, however, exhibits poor light transmissivity characteristics and thus limits the light-receiving efficiency of an CMOS image sensor and consequently it also limits any further improvement of this critical characteristic.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is to provide a CMOS image sensor and a method for fabricating the same, to improve the light-receiving efficiency of the image sensor by forming a microlens of a polymer exhibiting excellent transmissivity.

Additional features and advantages of the invention will be set forth in the description which follows, and in part will become apparent from the description, or may be learned from practice of the invention. The objectives and other advantages of the invention will be realized and attained by the structure particularly pointed out in the written description and claims hereof as well as the appended drawings.

To achieve these and other advantages in accordance with the purpose of the invention, as embodied and broadly described, there is provided a CMOS image sensor comprising at least one photodiode positioned on a semiconductor substrate; and a microlens disposed above each of the at least one photodiode, wherein the microlens is formed of a polymer material.

In another aspect of the present invention, there is provided a method for fabricating a CMOS image sensor comprising forming an insulating interlayer on a semiconductor substrate on which at least one photodiode is positioned; forming a polymer pattern in correspondence with the position of the at least one photodiode by first forming a polymer material layer and then patterning the polymer material layer; and reflowing the polymer material of the polymer pattern to form a microlens for directing incident light onto the at least one photodiode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principle of the invention.

In the drawings:

FIG. 1 is a cross-sectional view of a CMOS image sensor according to the related art;

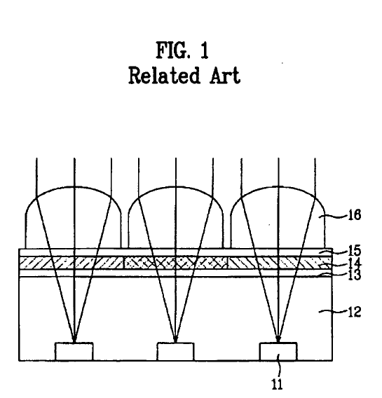

FIGS. 2A-2C are cross-sectional views of a process for fabricating a CMOS image sensor according to an exemplary embodiment of the present invention;

FIG. 3 is a cross-sectional view of a CMOS image sensor according to an exemplary embodiment of the present invention; and

FIGS. 4A-4C are cross-sectional views of a process for patterning the PMMA film in accordance with an exemplary embodiment of the present invention

### DETAILED DESCRIPTION OF THE INVENTION

Reference will now be made in detail to exemplary embodiments of the present invention, examples of which are illustrated in the accompanying drawings. Wherever possible, like reference numbers will be used throughout the drawings to refer to the same or similar parts.

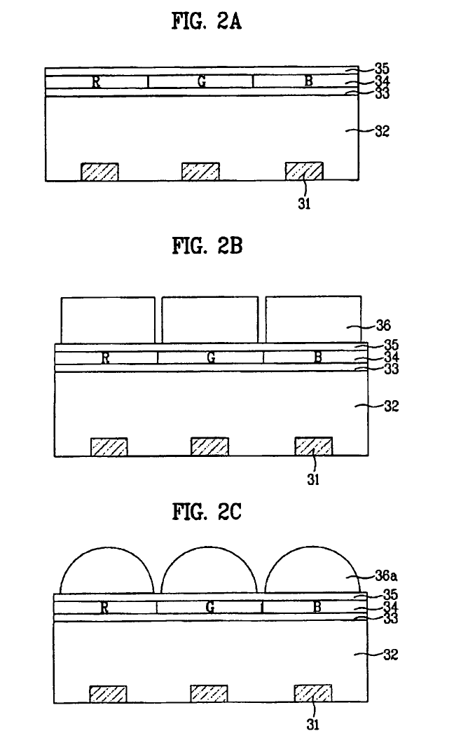

FIGS. 2A-2C illustrate a process for fabricating a CMOS image sensor according to an embodiment of the present invention.

Referring to FIG. 2A, at least one photodiode 31 for generating electrical charges according to the amount of incident light is disposed on a semiconductor substrate (not shown). In one embodiment, three such photodiodes per pixel unit of a color CMOS image sensor are arranged at fixed intervals. An insulating interlayer 32 is formed atop the photodiodes 31 to be in contact with surfaces of the semiconductor substrate and to completely cover the photodiodes. The insulating interlayer 32 may be formed as a multi-layered structure to include an optical-shielding layer (not shown), disposed between first and second depositions of the insulating interlayer material, for allowing incident light to reach each photodiode 31 and blocking light directed to areas of the semiconductor substrate not occupied by a photodiode. Subsequently, a passivation layer 33 is formed over the insulating interlayer 32 to protect the device from moisture contamination and damage due to abrasion.

For a color image sensor, a color filter layer 34 of colored resist is formed on the passivation layer 33 by coating and patterning a series of layers of colored resist in succession. The color filter layer may be formed by interlacing a plurality of color filters R, G, and B corresponding to the arrangement of the three photodiodes 31 and for respectively filtering light (red, green, and blue) of a predetermined wavelength. A planarization layer 35 is formed on the color filter layer 34, to control the focal distance and to obtain flatness (planarization) for forming a lens layer.

In FIG. 2B, a lens layer of a polymer material, for example, a polymethylmethacrylate (PMMA) film, is formed by polymerization or condensation and it is then deposited on the planarization layer 35. The PMMA film is adhered to the planarization layer via a thermal process at approximately 100° C. It should be appreciated that the initially formed (i.e., before patterning) polymer material layer is not specifically shown in the drawings.

Due to their high transparency (optical transmissivity), high strength, and specific UV radiation characteristics, PMMA films are often used as a substitute for glass, which exhibits a lower transmissivity (i.e., about 91%) than polymethylmethacrylate (i.e., about 93%). Polymethylmethacrylate is easily dissolved by an organic solvent such as isopropyl alcohol. Additionally, PMMA films have a heat deflection temperature of about 110° C. This low heat deflection temperature is advantageous in the thermal process performed when adhering the PMMA film to the planarization layer 35. During the thermal process, the PMMA film is heated to a temperature of about 100° C. to 200° C.

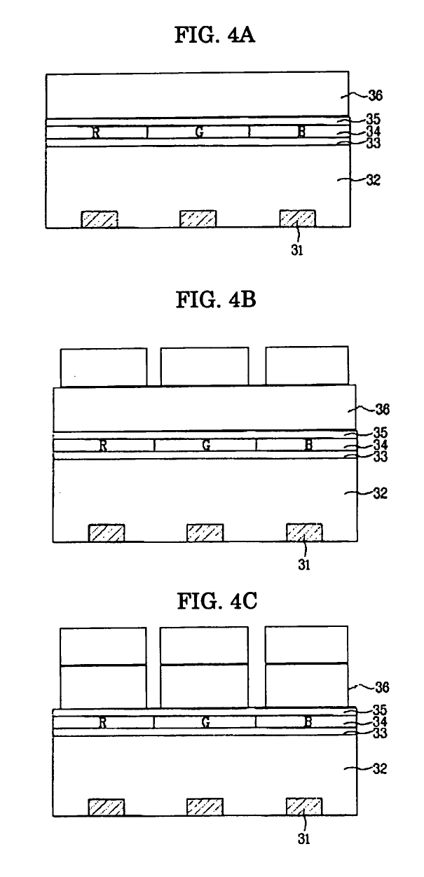

The PMMA film is selectively patterned by photolithography (a process of exposure and development followed by selective etching), thereby forming a PMMA pattern 36 in correspondence with the arrangement of the photodiodes 31 to maximize transmission of incident light. The width of each section of the obtained pattern is maximized with respect to the corresponding widths of the individual color filters of the color filter layer 34. Specifically, as shown in FIG. 4A, a photoresist is coated on the PMMA film 36. As shown in FIG. 4B the coated photoresist is patterned by exposure and development, to define a microlens area. As shown in FIG. 4C, using the patterned photoresist as a mask to selectively cover the PMMA film, the exposed portion of PMMA film is removed by etching using an organic solvent such as isopropyl alcohol or the like, leaving only the PMMA pattern 36. Finally, the photoresist layer (i.e., mask) is removed.

Referring to FIG. 2C, a separate thermal process is performed to the PMMA pattern 36 itself, namely, a reflow of the material (polymethylmethacrylate) of the patterned PMMA film. Reflow is a process whereby the upper surface of the patterned PMMA film is imparted with a smooth convex shape. This process is used to form a plurality of microlenses 36a, each having a predetermined curvature for respectively directing (focusing) incident light onto one of the underlying photodiodes 31. During the reflow process, the PMMA pattern 36 is heated to a temperature maintained at approximately 300-700° C.

A CMOS image sensor according to the present invention is shown in FIG. 2C. The CMOS image sensor specifically includes at least one photodiode 31 positioned on a semiconductor substrate (not shown) with the microlenses 36a respectively disposed above each photodiode. Each microlens is made of a film of polymer material, for example, polymethylmethacrylate, which is patterned and reflowed to form the individual microlenses. According to another embodiment of the present invention, or plurality of photodiodes are arranged on the semiconductor substrate at fixed intervals. FIGS. 2A-2C show an embodiment with the three photodiodes corresponding to the three primary colors of light, namely, red (R), green (G), and blue (B), of the color filter layer 34. The concept of the present invention can be equally applied to a monochrome image sensor.

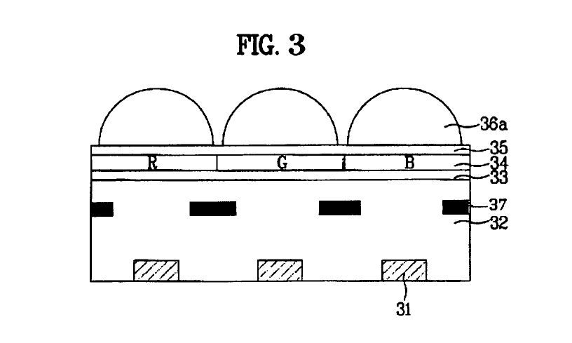

As shown in FIG. 3, the CMOS image sensor according to an exemplary embodiment of the present invention includes the insulating interlayer 32, an optical shielding layer 37, such as TiN, for allowing incident light to reach each photodiode 31 and blocking light directed to areas of the semiconductor substrate not occupied by any photodiode, the passivation layer 33, the color filter layer 34, and the planarization layer 35. The insulating interlayer 32 covers the photodiodes 31 and is formed on a surface of the semiconductor substrate and may include the optical shielding layer. The passivation layer 33 for protecting the at least one photodiode from moisture contamination and damage due to abrasion is applied to an upper part of the insulating interlayer. The color filter layer 34 is formed on the insulating interlayer 32 and has an interlaced plurality of color filters R, G, and B corresponding to the arrangement of the three photodiodes 31 and for respectively filtering light (red, green, and blue) of a predetermined wavelength. The planarization layer 33 is formed on the color filter layer 34 to occupy the entire upper surface of the semiconductor substrate and thus to control the focal length of the microlenses 36a and to provide a level (planarized) surface for receiving the microlenses, each of which has substantially the same width, or slightly less than, the corresponding color filter of the underlying color filter layer.

As described above, in a CMOS image sensor according to the present invention, a microlens for directing incident light onto an underlying photodiode is formed of the polymer material exhibiting excellent transmissivity and thereby enabling improved light-receiving characteristics.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A CMOS image sensor, comprising:
at least one photodiode positioned on a semiconductor substrate; and
a microlens disposed above each of said at least one photodiode,
wherein said microlens is formed of a polymer material.

2. The CMOS image sensor of claim 1, further comprising:
an insulating interlayer covering said plurality of photodiodes and being formed on a surface of the semiconductor substrate;
a color filter layer, formed over said insulating interlayer, having an interlaced plurality of color filters corresponding to the arrangement of the plurality of photodiodes; and
a planarization layer, formed on said color filter layer, for controlling a microlens focal length with respect to the arrangement of the plurality of photodiodes and for providing a planarized surface for receiving said microlens.

3. The CMOS image sensor of claim 2, wherein said insulating interlayer further comprises an optical shielding layer for allowing incident light to reach said at least one photodiode and blocking light directed to areas of the semiconductor substrate not occupied by said at least one photodiode.

4. The CMOS image sensor of claim 1, wherein the polymer material is polymethylmethacrylate.

5. The CMOS image sensor of claim 1, further comprising a passivation layer, formed on an upper part of said insulating interlayer, for protecting said at least one photodiode from moisture contamination and damage due to abrasion.

6. A method for fabricating a CMOS image sensor, comprising:
forming an insulating interlayer on a semiconductor substrate on which at least one photodiode is positioned;
forming a polymer pattern over and in correspondence with the position of the at least one photodiode by first forming a polymer material layer and then patterning the polymer material layer; and
reflowing the polymer material of the polymer pattern to form a microlens for directing incident light onto the at least one photodiode.

7. The method of claim 6, further comprising:
forming, on the insulating interlayer, a color filter layer having an interlaced plurality of color filters corresponding to the arrangement of the plurality of photodiodes; and
forming a planarization layer on the color filter layer, to control a microlens focal length with respect to the arrangement of the plurality of photodiodes and to provide a planarized surface for receiving the microlens.

8. The method of claim 7, further comprising:
adhering the polymer material to the planarization layer by a thermal process.

9. The method of claim 8, wherein the thermal process is performed at a temperature of approximately 100-200° C.

10. The method of claim 6, wherein the insulating interlayer is formed as a multi-layered structure.

11. The method of claim 10, wherein the multi-layered structure of the insulating interlayer includes an optical-shielding layer, disposed between first and second depositions of insulating interlayer material, for allowing incident light to reach each of the at least one photodiode and blocking light directed to areas of the semiconductor substrate not occupied by a photodiode.

12. The method of claim 6, further comprising:
forming, at an upper part of the insulating interlayer, a passivation layer for protecting the at least one photodiode from moisture contamination and damage due to abrasion.

13. The method of claim 6, wherein the polymer material layer comprises a polymethylmethacrylate film.

14. The method of claim 6, wherein the polymer material layer is formed by one of a polymerization process and a condensation process.

15. The method of claim 6, wherein the polymer pattern is formed by photolithography.

16. The method of claim 6, wherein said reflowing is performed at a temperature of approximately 300-700° C.

17. The CMOS image sensor, comprising:
a plurality of photodiodes positioned at fixed intervals on a semiconductor substrate;
an insulating interlayer formed over said plurality of photodiodes on a surface of the semiconductor substrate;
a color filter layer, formed on said insulating interlayer, having a plurality of color filters corresponding to said plurality of photodiodes; and
a plurality of microlenses of polymer material disposed in correspondence with the color filters of said color filter layer.
